(19) United States
(12) Patent Application Publication
(10) Pub. No.: US 2009/0304992 A1
(43) Pub. Date: Dec. 10, 2009

(54) Micro and Nano-Structure Metrology

(76) Inventors: Joseph M. Desimone, Chapel Hill, NC (US); Ginger D. Rothrock, Durham, NC (US)

Correspondence Address: MORGAN, LEWIS & BOCKIUS LLP, 1701 MARKET STREET, PHILADELPHIA, PA, 19103-2921, US

(21) Appl. No.: 11/990,243

(22) PCT Filed: Aug. 8, 2006
(86) PCT No.: PCT/US2006/030772

§ 371 Date: Feb. 3, 2009

Related U.S. Application Data
(60) Provisional application No. 60/706,850, filed on Aug. 8, 2005.

(51) Int. Cl. B32B 3/30; C23C 16/56

(52) U.S. Cl. 428/141; 427/8

(57) ABSTRACT

Materials and methods for performing microscopy include applying a curable liquid polymer to a surface or structure to be characterized and polymerizing the polymer. The polymerized polymer represents a mold of the structure or surface and can be analyzed without disrupting the surface or structure needing characterization. The materials also do not leave a residue or otherwise alter a surface chemistry of the structure characterized.

### CROSS REFERENCE TO RELATED APPLICATIONS

This application claims priority to U.S. Provisional application No. 60/706,850, filed Aug. 8, 2005; which is incorporated herein by reference in its entirety including all references cited therein.

### GOVERNMENT INTEREST

A portion of this application is based upon work supported in part by the STC Program of the National Science Foundation under Agreement No. CHE-9876674.

### TECHNICAL FIELD OF THE INVENTION

Generally, the present invention relates to the field of metrology. More particularly, the present invention provides efficient and effective methods and materials for accurately characterizing micro or nano-structures.

### BACKGROUND

There has always existed a need to accurately characterize manufactured structures. The structures need to be inspected for quality, compliance with specifications, consistency or reproduction, and the like in order to ensure proper operation of the component and interaction with other components of an assembly.

Recently, the scale of manufactured structures has reduced to the micro and nano-scale. With the reduction in size of today's manufactured structures, the importance of accurate characterization of these structures has increased because the structures are not visible for human inspection. However, techniques for characterizing micro and nano-structures have many drawbacks. For instance, today's scanning probe microscopy techniques, while sufficient to measure micro and nano structures that protrude from a surface, are insufficient to accurately measure micro and nano recesses in surfaces, particularly with high aspect ratio structures. Therefore, there exists a need in the art of metrology to identify small features. More particularly, there is a need in the art of metrology to accurately characterize embedded surface features in the tens of micron level down to sub-100 nm feature sizes.

### SUMMARY OF THE INVENTION

The present invention discloses a method of analyzing micro or nano-structures, including: applying a fluorinated elastomer-based prepolymer to a template defining a micro or nano-structure; removing the fluorinated elastomer-based polymer from the template having a micro or nano-structure; and characterizing attributes of the micro or nano-structure. The present invention further includes polymerizing the fluorinated elastomer-based polymer after it is applied to the template. The fluorinated elastomer-based polymer of the present invention is a low surface energy fluorinated elastomer-based polymer. The surface energy is less than about 30 dynes/cm. The surface energy is between about 7 dynes/cm and about 20 dynes/cm. The surface energy is between about 8 dynes/cm and about 15 dynes/cm. The fluorinated elastomer-based polymer is selected from the group including of PFPE and PDMS. The fluorinated elastomer-based polymer further includes a photocurable constituent. The fluorinated elastomer-based polymer further includes a thermal curable constituent. The fluorinated elastomer-based polymer further includes a mixture of a photocurable constituent and a thermal curable constituent. The micro and/or nano-structures are less than about 200 nm in diameter. The micro and/or nano-structures are less than about 100 nm in diameter. The fluorinated elastomer-based polymer is liquid at room temperature. The present invention also includes treating the polymer template combination to ensure the polymer conforms to the micro and/or nano-structures of the template, wherein the treating includes vibration, centrifugal forces, and vacuum.

The present invention also discloses a product for characterizing micro and/or nano-structures, including: a polymerized polymer mold made by the process of; treating a template defining a micro and/or nano-structure with a polymer; curing the polymer; removing the polymer form the template such that the polymer represents a mold replica of the micro and/or nano-structure of the template; and characterizing the mold replica of the micro and/or nano-structure.

In some embodiments, a component being molded for characterization is substantially free from any residual substance following removing the cured substance from the component. In other embodiments, a volume of the substance before the curing is substantially equivalent to a volume of the cured substance after the curing. In some embodiments, the substance substantially does not absorb hydrocarbon solvents. In other embodiments, the substance does not swell more than about 10 percent by weight in the presence of a hydrocarbon solvent. In yet other embodiments, the cured substance has a wetting angle of less than about 90 degrees. According to some embodiments, the perfluoropolyether includes a molecular weight of between about 500 and about 5000.

In some embodiments, the endcapping group of the polymer includes a polymerizable group and in alternative embodiments, the polymerizable group includes an acrylate, a methacrylate, an epoxy, a styrenic group, or combinations thereof. In some embodiments, the substance includes a siloxane, such as a poly(dimethyl siloxane). In other embodiments, the substance includes a polymer such as a fluoropolymer having a thermal-curable functional group. In some embodiments, the curable polymer includes a fluoropolymer having a photocurable functional group. In other embodiments, the photocurable functional group includes a photocurable diurethane methacrylate. In some embodiments, the photocurable functional group includes a photocurable diepoxy. In other embodiments, the curable polymer includes a fluoropolymer having more than one of the following; a photocurable functional group, a thermal-curable functional group. According to some embodiments, a wafer metrology device includes a cured polymer replica of a patterned silicon wafer configured and dimensioned from a liquid polymer deposited on the patterned silicon wafer and cured thereupon. In other embodiments, the polymer includes a low surface energy polymeric material. In some embodiments, the polymer includes a fluoropolymer such as perfluoropolyether. In some embodiments, the silicon wafer includes a dual damascene structured wafer. In other embodiments, the polymer includes a photocurable polymer. In some embodiments, the fluoropolymer includes a photocurable perfluoropolyether. In other embodiments, the photocurable perfluoropolyether includes a photocurable diurethane methacrylate function group. In still other embodiments, the photocurable perfluoropolyether includes a photocurable diepoxy functional group.

According to some embodiments, a metrology device includes a replicate of a component, wherein the replicate comprises a photocured polymer replica of the component fabricated from photocuring a liquid photocurable polymer in communication with the component. According to some embodiments, the polymer includes a fluoropolymer such as a perfluoropolyether. In some embodiments the polymer includes a low surface energy polymeric material.

According to some embodiments, a metrology system includes removing a patterned silicon wafer from processing, introducing a liquid curable polymer to the patterned silicon wafer, curing the curable polymer to form a mold of the patterned silicon wafer, removing the cured polymer mold from the patterned silicon wafer, performing metrology on the cured polymer mold of the patterned silicon wafer, and returning the patterned silicon wafer to processing. In some embodiments, the cured polymer mold substantially does not leave residual polymer on the patterned silicon wafer. In some embodiments, the polymer includes a fluoropolymer such as a perfluoropolyether. In other embodiments, the curable polymer includes a liquid perfluoropolyether having a photocurable functional group. In some embodiments, the photocurable functional group is selected from diurethane methacrylate or diepoxy. In other embodiments, the system includes using at least a portion of the patterned silicon wafer in an application.

### BRIEF DESCRIPTION OF THE DRAWINGS

Reference is made to the accompanying drawings in which are shown illustrative embodiments of the invention, from which its novel features and advantages will be apparent.

FIG. 1 shows a method of forming a replica mold for metrology of micro and/or nano-structures according to an embodiment of the present invention;

FIGS. 2A-2C shows a template and a mold corresponding to the template according to an embodiment of the present invention; and

FIGS. 3A-3C show cross-sectional characterization of micro and/or nano-structures of a template, according to another embodiment of the present invention;

FIGS. 4A-4B show cross-sectional characterization of micro and/or nano-structures of a template, according to an embodiment of the present invention;

FIGS. 5i and 5ii shows x-ray photoelectron spectroscopy plots of a patterned surface pre-molding, post-molding, and post cleansing according to an embodiment of the present invention; and

FIG. 6 shows patterned surfaces and replica molds fabricated therefrom according to embodiments of the present invention.

### DESCRIPTION

Reference will now be made in detail to preferred embodiments of the present invention, examples of which are illustrated in the accompanying drawings. Wherever possible, the same reference numbers will be used throughout the drawings to refer to the same or like parts. To provide a thorough understanding of the present invention, numerous specific details of preferred embodiments are set forth including material types, dimensions, and procedures. Practitioners having ordinary skill in the art will understand that the embodiments of the invention may be practiced without many of these details. In other instances, well-known devices, methods, and processes have not been described in detail to avoid obscuring the invention.

The presently disclosed subject matter broadly applies to methods and materials for accurately measuring or characterizing micro and nano-structures. The methods and materials generally include casting liquid materials onto a template having microstructures and/or nanostructures, curing the liquid materials to generate a patterned mold of the micro or nano-structures, and characterizing the mold of the micro or nano-structures. Because the materials of the present invention do not alter the surface energy of material molded or leave residue on the surface or structure after they are cured, the mold provides accurate characterization of micro or nano-structures without damaging or interfering with the sample being measured or characterized. Many applications can benefit from the disclosed materials and methods including, but not limited to, semiconductor manufacturing, MEMS; crystals; materials for displays; photovoltaics; solar cell devices; optoelectronic devices; routers; gratings; radio frequency identification (RFID) devices; etch barriers; scanning probe microscopy components such as AFM tips; parts for nano-machines; and shapes of any kind that will enable the nanotechnology industry.

### I. Introduction

According to some embodiments, a template can be any device that includes micro or nano-structures that need to be characterized. Characterizing a structure or surface can mean, in some embodiments, but is not limited to, measuring, scanning, inspecting, graphically representing or reading, including computer generated graphic representation, or the like. For example, some common templates that require frequent characterization during manufacture include, but are not limited to, micro electronic devices, semiconductor wafers, medical implant surface structures, and the like. Many templates contain structures such as holes, vias, trenches, lines, three dimensional structures, or other recessed structures to be characterized that are less than about 500 nanometers in a dimension. In other embodiments, the structures are less than about 200 nanometers in a dimension. In yet other embodiments the structures in the templates are less than about 100 nanometers in a dimension.

The use of soft, elastomeric materials, such as for example, perfluoropolyether, polydimethylsiloxane (PDMS), and the like offer numerous properties for metrology. Such elastomers are highly UV transparent and have a low Young's modulus (e.g., less than about 100 MPa) which gives them flexibility required for conformal contact with surfaces to be characterized. Conformal contact has proven to be important for soft lithography techniques because it allows the stamp to conform to surface irregularities without generating defects or resulting in the cracking of stamps which can occur with stamps made from brittle, high-modulus materials like etched silicon and glass. The chemical resistance of perfluoropolyether based materials is another characteristic of the material that aids in the patterning of a variety of organic resins, including but not limited to etch resists, low-k dielectrics, silicon wafers, conducting polymers, combinations thereof, and the like.

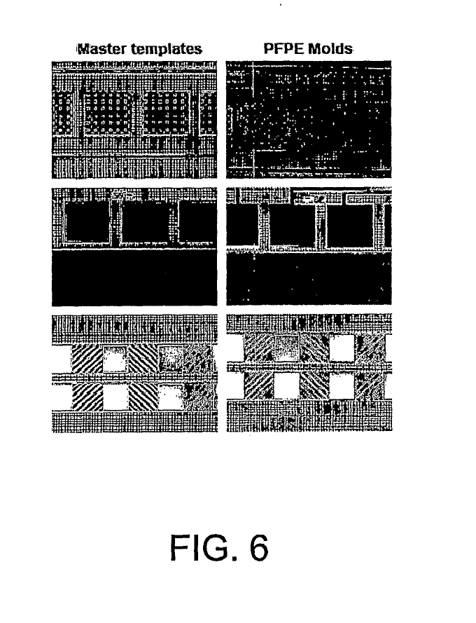

According to some embodiments, polymeric molds, such as for example, photocurable perfluoropolyethers can be fabricated from the materials described herein to replicate features on a patterned master in the order of tens of nanometers. Such materials are substantially resistant to swelling by organic liquids, and have been demonstrated for use in molding patterned nanometer (e.g., 70 nm) features with a high precision (e.g., +/−1 nm), as disclosed in Rolland, J. P., et al., J. Am. Chem. Soc., 2004. 126: p. 2322-2323; and J. P. Rolland, E. Hagburg, G. Denison, K. Carter, and J. M. DeSimone, “High Resolution Soft Lithography: Enabling Materials for Nanotechnology,” Angewandte Chemie, vol 43, pp 5796-5799, 2004; each of which is incorporated herein by reference in its entirety including all reference cited therein. FIG. 6 shows a variety of patterned master and polymer molds fabricated according to materials and methods of the present invention.

### II. Materials

In some embodiments, the materials for the mold include, but are not limited to, a polymeric material, such, as but not limited to, siloxanes, silanes, methacrylates, acrylates, fluoropolymers, and small molecule fluorinated monomers, such as for example an acrylate, a methacrylate, a styrene, an epoxy, a carboxylic, an anhydride, a maleimide, an isocyanate, an olefinic, an amine, combinations thereof, and the like. In other embodiments, the material for the mold is made by the polymerization of materials including one or more of the following: prepolymers, monomers, macromonomers, and the like. In other embodiments, the material for the mold includes a solvent resistant, elastomer-based material, such as but not limited to a fluorinated elastomer-based material. As used herein, the term “solvent resistant” refers to a material, such as an elastomeric material that neither swells nor dissolves in common hydrocarbon-based organic solvents or acidic or basic aqueous solutions beyond a given percentage. In some embodiments, the high resistance to swelling by organic liquids includes swelling less than about 10 percent by weight in the presence of hydrocarbon solvents. In other embodiments, the high resistance to swelling by organic liquids includes swelling less than about 8 percent by weight in the presence of hydrocarbon solvents. In alternative embodiments, the high resistance to swelling by organic liquids includes swelling less than about 5 percent by weight in the presence of hydrocarbon solvents.

In some embodiments, the materials disclosed herein for conducting metrology are liquid at room temperature and can be cured (e.g., photochemically or thermal-chemically) cross-linked to yield tough, durable, elastomers. In some embodiments, the materials are highly fluorinated, thus exhibiting high resistance to swelling by organic liquids and, therefore, allowing for patterning of a variety of organic resins including etch resists, low-k dielectrics, silicon wafers, dual damascene structures and other nano-scale patterns. In other embodiments, the material may not be liquid at room temperature, however, the material can be heated to transform into a liquid or substantially or partially into a liquid before being applied to a structure of a template to be molded. After being applied to the template the material is capable of cooling and solidifying, thereby taking on the shape of the micro and/or nano-structures of the template.

For the sake of simplicity and ease of reading, predominate portions of this specification will make reference to fluorinated elastomeric materials, such as perfluoropolyether, however, it should be appreciated that all materials, compositions, mixtures, combinations, techniques, etc, disclosed herein can be equally applied and are encompassed in this disclosure.

According to a preferred embodiment, the material for molding a structure of a template is a low surface energy elastomeric material that is liquid at room temperature or liquid at less than a high temperature (e.g., below about 100 degrees C.). The low surface energy elastomeric material facilitates separation of the mold from the template with minimal defects introduced into the mold upon separation from the template. The wetting properties of the material can improve compliance between the material for the mold and the micro or nano-structures of the template such that the mold accurately represents the micro or nano-structures. According to some embodiments, the materials described herein have a low surface energy wherein a low surface energy is a surface energy below about 30 dynes/cm. In alternative embodiments, the surface energy includes a surface energy less than about 20 dynes/cm. In some embodiments, the low surface energy includes a surface energy below about 15 dynes/cm. In alternative embodiments, the surface energy includes a surface energy less than about 12 dynes/cm. In some embodiments, the surface energy includes a surface energy less than about 10 dynes/cm. In other embodiments, the substance to be cured has a wetting angle of less than about 90 degrees.

According to another embodiment, the material for the mold includes a curable precursor constituent that initiates polymerization, or a hardening or solidification of the material upon exposure to a stimulant. In some embodiments, the material for the mold can include photocurable precursor or a thermalcurable precursor constituent that initiates polymerization of the material upon exposure to a particular UV light or temperature, respectively. In other embodiments, the material for the mold can include combinations of photocurable polymerization initiation precursors that activate at different wavelengths or a combination of thermalcure polymerization initiation precursors that activate at different temperatures or following exposure to a given temperature for a predetermined amount of time. In a preferred embodiment, a photocurable liquid PFPE exhibits desirable properties for soft lithography.

A representative scheme for the synthesis and photocuring of functional PFPEs is provided in Scheme 1.

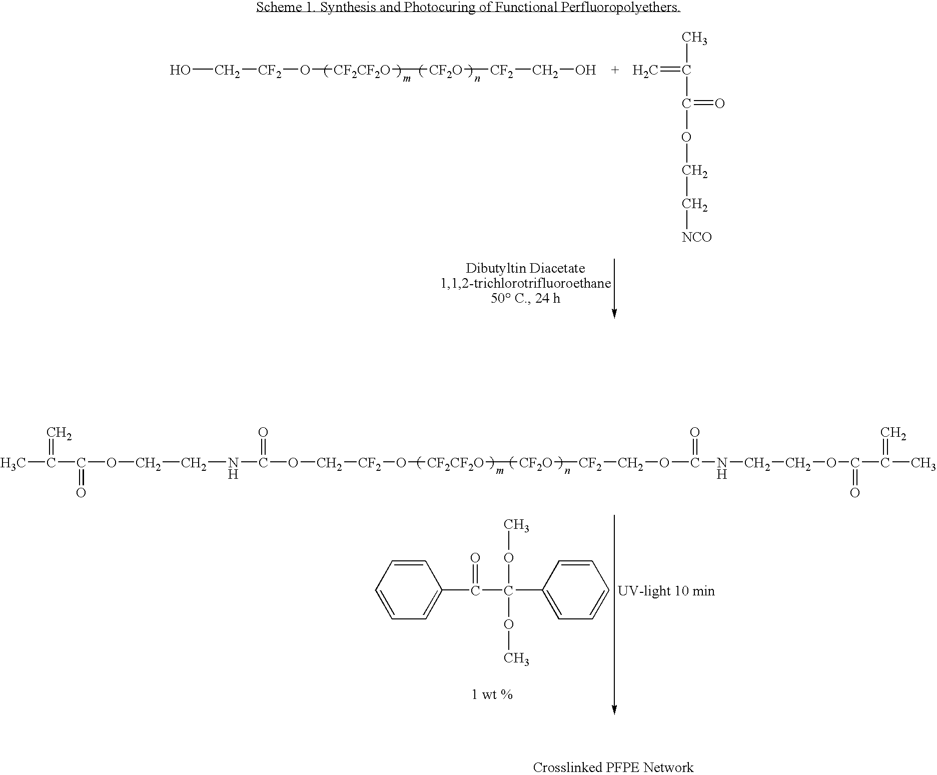

In some embodiments, the PFPE material has a low surface energy, for example, about 12 dynes/cm. The PFPE is also UV transparent, highly gas permeable, and cures into a tough, durable, highly fluorinated elastomer with excellent release properties and resistance to swelling, and has a molecular weight of between about 500 and about 5000. The properties of these materials can be tuned over a wide range through the judicious choice of additives, fillers, reactive co-monomers, and functionalization agents. Such properties that are desirable to modify, include, but are not limited to, modulus, tear strength, surface energy, permeability, functionality, mode of cure, solubility and swelling characteristics, and the like. The non-swelling nature and easy release properties of the presently disclosed perfluoropolyether materials allows for imprinting or molding of templates of many different materials.

In some embodiments, the material for molding micron or nano-structures includes a material selected from the group including a perfluoropolyether material, a fluoroolefin material, an acrylate material, a silicone material, a styrenic material, a fluorinated thermoplastic elastomer (TPE), a triazine fluoropolymer, a perfluorocyclobutyl material, a fluorinated epoxy resin, a fluorinated monomer or fluorinated oligomer, small molecule fluorinated monomer, or the like that can be polymerized or crosslinked by a metathesis polymerization reaction.

In some embodiments, the perfluoropolyether material includes a backbone structure selected from the group including:

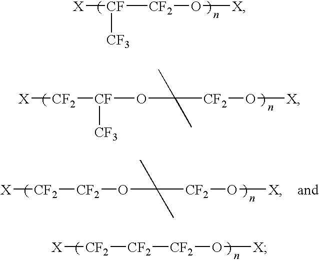

wherein X is present or absent, and when present includes an endcapping group. In some embodiments, the fluoroolefin material is selected from the group including:

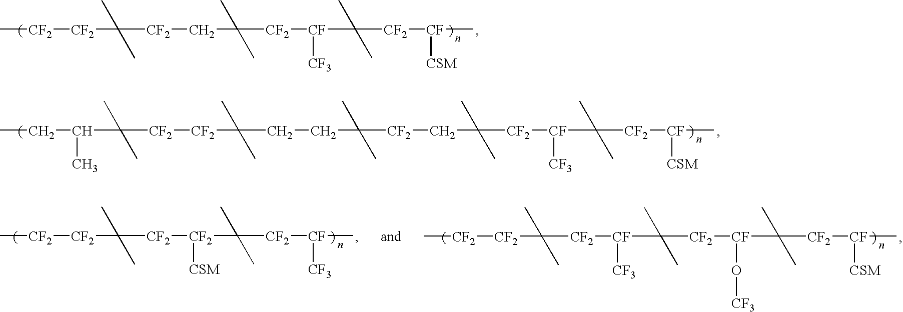

wherein CSM includes a cure site monomer.

According to some embodiments, the photocurable functional group associated with the polymers of the present invention include a photocurable diurethane methacrylate.

Alternatively, in some embodiments, the photocurable functional group includes a photocurable diepoxy.

In some embodiments, the photocurable functional group includes a photocurable diurethane methacrylate functionalized perfluoropolyether having a structure of:

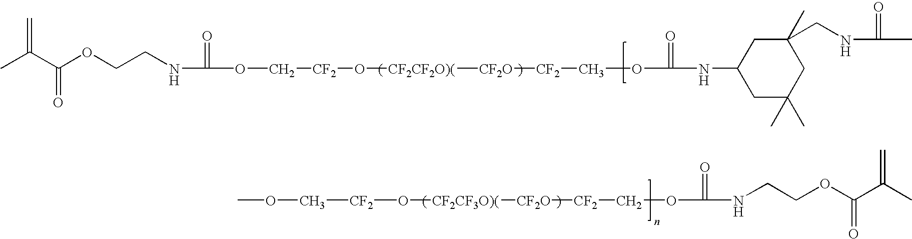

In alternative embodiments, the photocurable functional group includes a photocurable diurethane methacrylate functionalized perfluoropolyether having a structure of:

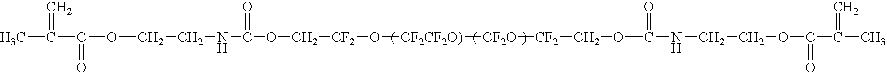

In some embodiments, the photocurable functional group includes a photocurable diurethane methacrylate functionalized perfluoropolyether having a structure of:

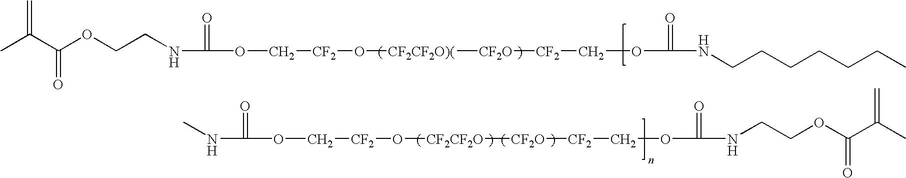

In other embodiments, the photocurable functional group includes a photocurable diepoxy functionalized perfluoropolyether having a structure of:

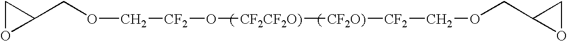

In some embodiments, the material used for fabricating molds of micro and/or nano-structures includes a fluoroolefin material. According to some embodiments, the fluoroolefin material is made from monomers which include tetrafluoroethylene, vinylidene fluoride, hexafluoropropylene, 2,2-bis(trifluoromethyl)-4,5-difluoro-1,3-dioxole, a functional fluoroolefin, functional acrylic monomer, and a functional methacrylic monomer.

In some embodiments, the material used for fabricating molds of micro and/or nano-structures includes a silicone material. According to some embodiments, the silicone material includes a fluoroalkyl functionalized polydimethylsiloxane (PDMS) having the following structure:

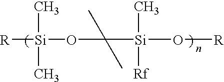

wherein:
R is selected from the group including an acrylate, a methacrylate, and a vinyl group; and
Rf includes a fluoroalkyl chain.

In some embodiments, the material used for fabricating molds of micro and/or nano-structures includes a styrenic material. According to some embodiments, the styrenic material includes a fluorinated styrene monomer selected from the group including:

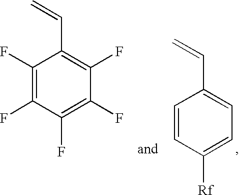

wherein Rf includes a fluoroalkyl chain.

In other embodiments, the material used for fabricating molds of micro and/or nano-structures includes an acrylate material. According to some embodiments, the acrylate material includes a fluorinated acrylate or a fluorinated methacrylate having the following structure:

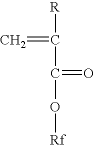

wherein:
R is selected from the group including H, alkyl, substituted alkyl, aryl, and substituted aryl; and
Rf includes a fluoroalkyl chain.

In some embodiments, the material used for fabricating molds of micro and/or nano-structures includes a triazine fluoropolymer including a fluorinated monomer. According to other embodiments, the fluorinated monomer or fluorinated oligomer that can be polymerized or crosslinked by a metathesis polymerization reaction includes a functionalized olefin. In yet other embodiments, the functionalized olefin includes a functionalized cyclic olefin.

From a property point of view, the exact properties of these molding materials can be adjusted by adjusting the composition of the ingredients used to make the materials, as will be appreciated by one of ordinary skill in the art. In some embodiments, the modulus can be adjusted from approximately 500 kPa to multiple GPa.

According to another embodiment, the material for the mold is preferably optically transparent to facilitate interrogation and inspection of the mold for defects using optical methods. In other embodiments, materials that can be used as the materials of the present invention include the materials disclosed in U.S. Provisional applications 60/544,905, filed Feb. 13, 2004; 60/706,786, filed Aug. 9, 2005; 60/732,727, filed Nov. 2, 2005; 60/799,317, filed May 10, 2006 and PCT application WO/05084191A2, filed Feb. 14, 2005, each of which is incorporated herein by reference in its entirety including all references cited therein.

### III. Methods

Methods for fabricating molds of patterned surfaces or micro and/or nano-structures and performing metrology thereon to characterize the patterned surface or structure are hereinafter described. Generally, materials of the present invention are introduced to a surface or structure to be measured or characterized. The materials are preferably in liquid or semi-liquid form and curable by, for example, photo-curing or thermal-curing. Next, the material is cured on the surface or structure and removed after they are cured. Once the materials are cured and removed, the mold represents a mirror image of the micro and/or nano-structure or patterned surface to be characterized and metrology can be performed on the mold. Furthermore, in some embodiments, following the removal of the cured polymer mold from the template, the template can be returned to the manufacturing step from which it was taken (to be characterized) and used in a completed product because the materials of the present invention do not disrupt or destroy the template. According to some embodiments, a cast or mold is made of the patterned template or surface by treating or applying the materials of the present invention onto the template. According to an embodiment, the casting or molding is achieved by pouring materials of the present invention on a surface of the template or substantially encasing a structure with the materials. In some embodiments, the materials can be introduced onto the template by spraying, dripping, spreading, layering, pouring, heating then pouring, heating then spreading, heating then spraying, or the like. According to a preferred embodiment, the material for the mold is introduced to the template in a liquid form. In other embodiments, the material is applied to the template in an aerosol form. In still other embodiments, the material is applied to the template in a semi-solid form, such as for example, a thin layer that is pressed onto the template to conform to micro and/or nano-structures of the template. In other embodiments, the template is introduced to the materials for the mold such that either a portion of the template is treated with the materials or the entire template is treated with the materials.

After the material for the mold is introduced to the template the material is cured such that it solidifies and forms a solid mold. Because the material preferably has a low surface energy, the material easily releases from the micro and/or nano-structures of the template and provides a mirror image or negative image of the micro and/or nano-structures of the template. Furthermore, the structures of the mold that correspond to the micro and/or nano-structure recesses are projections and protrude from the surface of the mold. As conventional metrology techniques are much more adapted to measuring micro and/or nano-projections as opposed to recesses, metrology characterization of the mold yields a more accurate and efficient characterization of the micro and/or nano-structures than a metrology characterization of the recesses themselves. The mold created from this template is the mirror image, and thus contains raised features that can be examined more easily. In some embodiments, the mold created from the template is also optically transparent, which allows for improved optical inspection techniques including through-film metrology. Furthermore, because the materials of the present invention do not interfere or react with the material of the template or structure to be characterized and do not leave residue on the surface following removal of the cured mold from the surface or structure, the present methods and materials provide a non-destructive technique for micro and/or nano-structure metrology.

According to some embodiments, the materials and methods of the present invention can be used to make a wafer metrology device. In some embodiments, the wafer metrology device is fabricated from a cured polymer replica of a patterned silicon wafer configured and dimensioned from a liquid prepolymer deposited on the patterned silicon wafer and cured thereupon. Preferably, the wafer metrology device includes a polymer includes a low surface energy polymeric material. In some embodiments, the polymer is a fluororopolymer (e.g., perfluoropolyether) and in some embodiments, this fluoropolymer includes a functional group, such as but not limited to a photocurable functional group. According to some embodiments the combination of the template with the material for the mold is treated to facilitate conformity between the material for the mold and the structures of the template, including but not limited to the micro and/or nano-structures. Examples of such treatment techniques include, but are not limited to, application of gravitational forces such as vibration or centrifugal forces. According to a further embodiment, the template can be subjected to a vacuum environment prior to introduction of the mold materials to the template such that the mold materials, when applied to the template, substantially completely conform with the structures of the template, including but not limited to the micro and/or nano-structures. According to some embodiments, the wafer metrology device is a mold of a dual damascene structured wafer.

In other embodiments, the present invention discloses a metrology system. The metrology system generally includes removing a patterned silicon wafer from processing, such as where the silicon wafer is in production and ready for analysis. Next, prepolymer materials of the present invention are introduced onto that silicon wafer and the prepolymer is cured thereon such that a mold of the pattern on the silicon wafer is molded in the polymer. Next, the cured polymer mold is removed from the patterned silicon wafer and metrology is performed on the cured polymer mold. After the mold is inspected and passes a threshold the silicon wafer can be returned to processing such that the silicon wafer is not a loss of production. Alternatively, defects that are found during inspection can be repaired in a separate process.

According to some embodiments, the method for performing metrology includes depositing a substance into communication with a component to be characterized, wherein the substance includes a low surface-energy curable polymer. Next, the substance is cured such that a mold of the component is formed. Next, the cured substance is removed from the component to reveal a mirror replica of the component. Then, the mold is inspected to characterize the component. In some embodiments, the component is substantially free from any residual substance following removing the cured substance from the component. In other embodiments, the component is free from residual substance following removing the cured substance from the component. In some embodiments, the volume of the substance before the curing is substantially equivalent to a volume of the cured substance after the curing. According to some embodiments, the substance of the mold does not swell more than about 10 percent by weight in the presence of a hydrocarbon solvent. In alternative embodiments the methods of the present invention include the steps of depositing a substance into communication with a patterned surface of a silicon wafer to be characterized, wherein the substance includes a low surface-energy curable polymer. Next, the substance is cured such that a mold of the patterned surface is formed. Next, the cured substance is removed from the patterned surface and the molded surface is characterized for defects in the silicon wafer.

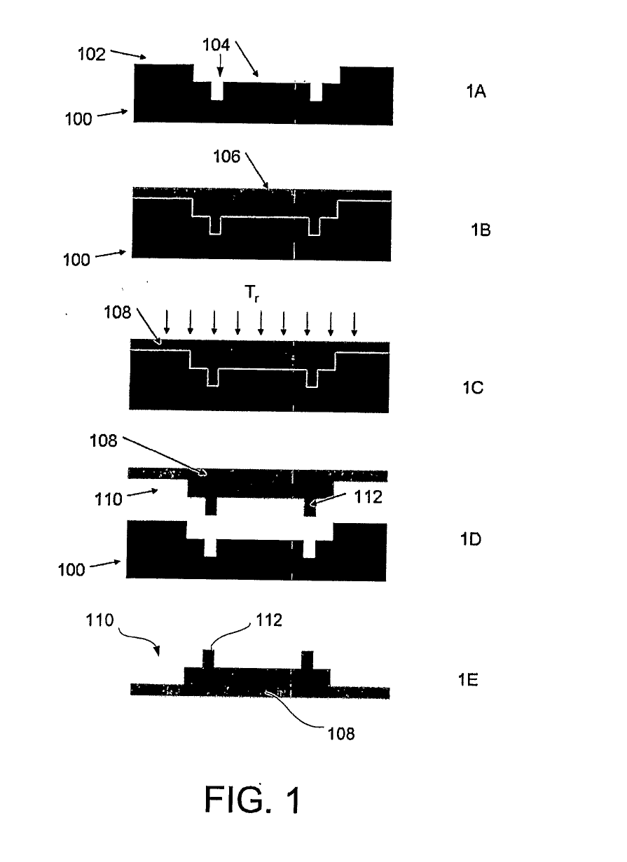

Referring now to the Figures, FIG. 1A shows a patterned template 100 having micro and/or nano-structures thereon. Template 100 can include a plurality of non-recessed surface areas 102 and a plurality of recesses 104. In some embodiments, template 100 includes an etched substrate, such as a silicon wafer, that is etched in a desired pattern. In some embodiments, template 100 includes a patterned low-K dielectric material. In some embodiments, template 100 includes a patterned metal.

Referring now to FIG. 1B, a liquid material 106, for example, a liquid fluoropolymer composition, such as a photocurable perfluoropolyether based precursor, is then deposited onto template 100. Referring now to FIG. 1C, liquid material 106 is treated by treating process Tr, for example by exposure to UV light, thereby polymerizing liquid material 106 and forming a treated liquid material 108. Treated liquid material 108 includes structures 110 and 112, which are mirror image structures of recessed surface area 102 and recesses 104 of template 100.

Referring now to FIG. 1D, treated liquid material 108 is removed from template 100. As shown in FIGS. 1C and 1D, treated liquid material 108 includes structures 110 and 112, which correspond to recessed surface area 102 and recesses 104. As shown in FIG. 1E, treated liquid material 108 can now be used for metrology applications by characterizing or measuring structures 110 and 112 of treated liquid material 108. In alternative embodiments, treated liquid material 108 can be used as a mold for casting another curable liquid polymer such that a replica of template 100 can be formed. According to such embodiments, this replica of template 100 is not a mirror image of template 100, but an actual replica of template 100 and can be characterized to represent template 100.

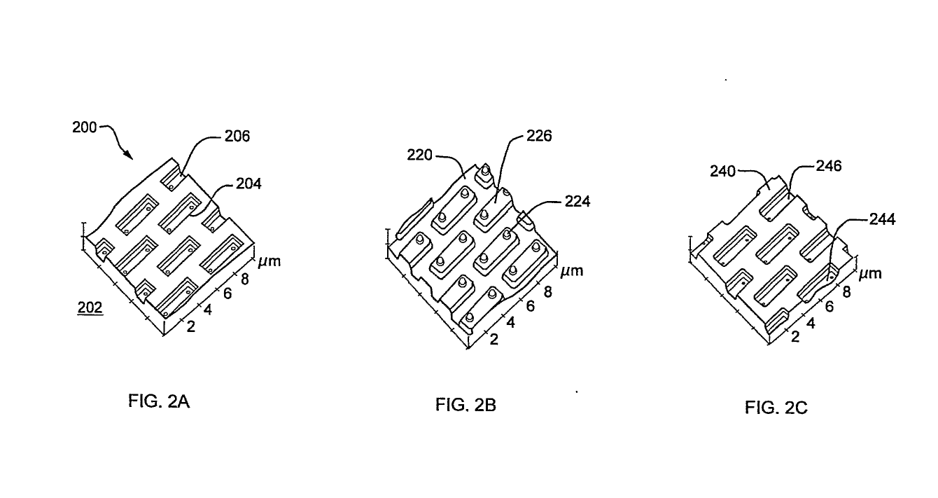

Referring now to FIGS. 2-4, a method of the metrology of the present invention will now be described. FIG. 2A shows a template 200 to be analyzed using the materials and methods of the present invention. The template includes micro and/or nano-structures 204 and 206 shown as recesses in the surface 202. However, it will be appreciated that micro and/or nano-structures 204,206 can be any structures to be analyzed or characterized. In a preferred embodiment, micro and/or nano-structures 204,206 can be dual damascene structures. FIG. 2B is a mold replica 220 of the template 200 of FIG. 2A. Mold replica 220 includes projections 224 and 226 that correspond to recesses 204 and 206, respectively, of template 200 of FIG. 2A. Mold replica 220 is fabricated by applying materials of the present invention to template 200 and allowing the materials to polymerize or cure. Once cured, the mold replica 220 is removed from template 200 and the recesses of the template 200 are represented by protrusions of the mold replica 220. FIG. 2C shows a molded replica 240 of mold replica 220. To fabricate molded replica 240, mold replica 220 is cast with a curable liquid polymer such that the curable liquid polymer coats mold replica 220. The curable liquid material is then cured or polymerized such that a mold 240 if formed of mold replica 220. Molded replica 240 includes replica structures 244 and 246 that correspond with recesses 204, 206 and 224 and 226, respectively.

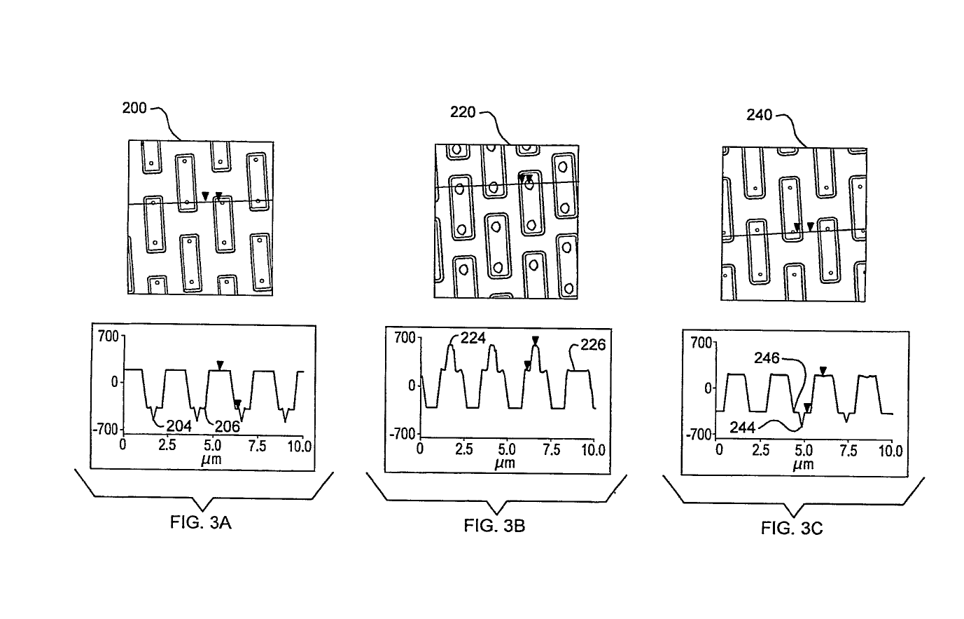

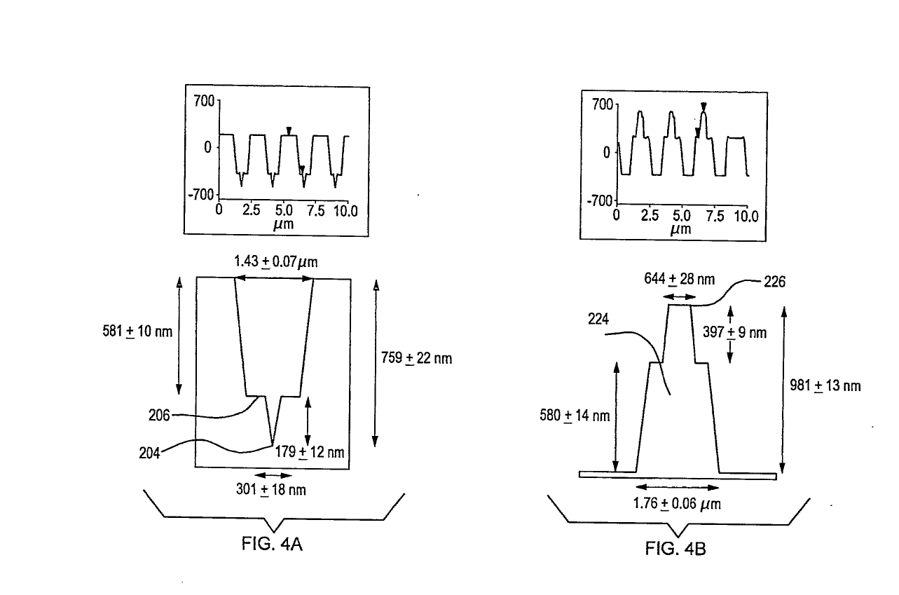

Referring now to FIG. 3, FIGS. 3A, 3B, and 3C correspond to FIGS. 2A, 2B, and 2C but are shown in cross-section. Cross-section FIG. 3A shows measurement characterizations of the surface of template 200 including the recesses 204 and 206. FIG. 3B is a cross-section of measurement characterizations of the mold replica 220 of FIG. 2B where protrusions 224 and 226 are the mirror images of recesses 204 and 206, respectively. As can be seen from the measurements of the cross-sections between FIGS. 3A and 3B, the mold replica 220 in FIG. 3B represents an accurate replica of the surface micro and/or nano-structures of template 200. FIGS. 4A-4B shows similar date to that of FIGS. 3A-3C but in a more magnified view.

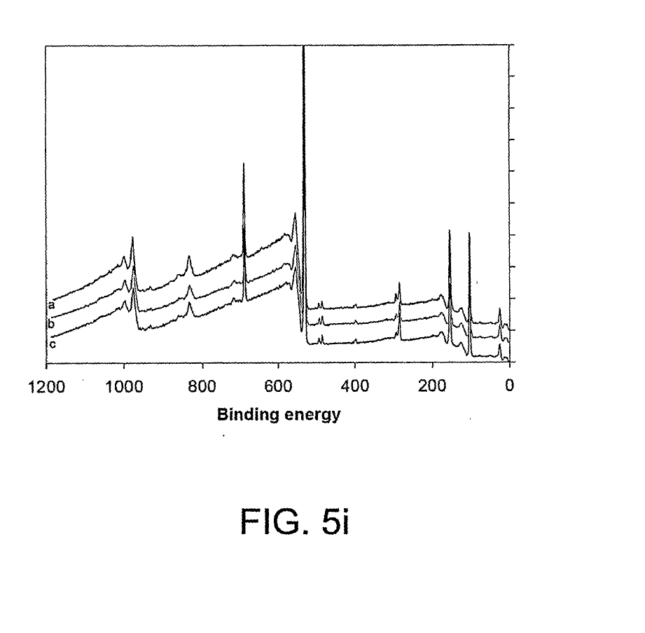

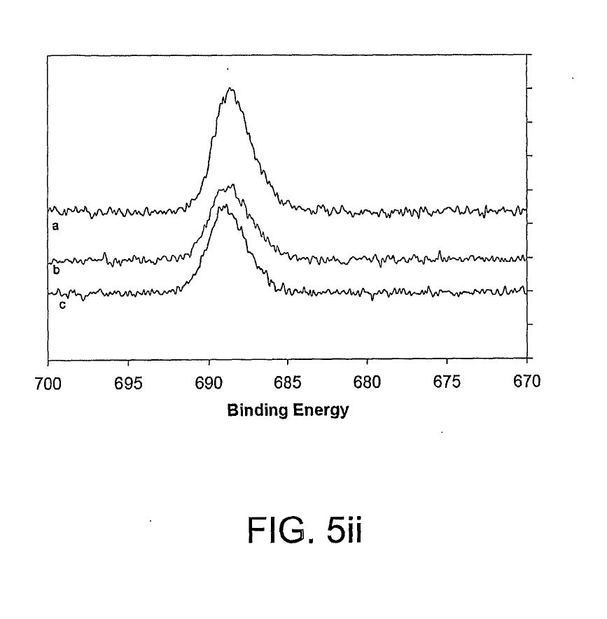

FIG. 5 shows X-ray Photoelectron Spectroscopy (XPS) of a wafer surface before (a) and after patterning (b), as well as patterning followed by a 5 second rinse with perfluorohexanes (c). In FIG. 5, the XPS spectra data is data of a dual damascene wafer before and after molding with perfluoropolyether materials. FIG. 5i shows survey spectra of the dual damascene master prior to molding (a); following molding with 4000 MW perfluoropolyether precursors (b); and after molding with 4000 MW perfluoropolyether precursors and a brief perfluorohexane wash (c). The shape of the curve, (i.e., area under the curve), indicates the chemical composition (measured as the energy of electrons at the surface) of the wafer prior to and after imprint molding with the materials and methods of the present invention. The similarity of the curve shape and area under the curves (a), (b), and (c) represent that the chemical composition of the wafer is substantially un-changed by the metrology techniques of the present invention. The lines corresponding to a, b, and c, of FIGS. 5i and 5ii have been arbitrarily separated in y-axis value such that the lines could be differentiated. If the lines had not been manually separated they would have overlapped and negated any attempt at comparison between the lines. One of skill in the art will appreciate that the lines indicate the similarity in surface characterization pre and post mold fabrication. FIG. 5ii, shows a higher resolution of the samples given in FIG. 5i where electrons from the fluorine 1s orbital would appear. Accordingly, FIG. 5ii shows that the chemical composition of the surface has not changed. Looking more closely at the F 1s spectra, see FIG. 5ii, it is shown that the fluorine content at the surface has not changed, therefore, the fluorinated polymer does not cause additional fluorine contamination of the wafer surface.

### IV. Methods for Inspection of the Mold

The molds representing the negative of the micro and/or nano-structures of the template can be measured, graphed, computer analyzed, and further characterized following removal of the mold from the template. Inspection of the molds can allow for corrective actions to be taken and adjustments thereto made to the template to correct possible defects. Alternatively, defects of a template can be identified and removed or mitigated from the original template at an early stage in development and/or production.

The present invention is not limited to the type of characterization device to be used in measuring and/or characterizing the mold. Examples of such characterization techniques include, but are not limited to air gauges, which use pneumatic pressure and flow to measure or sort dimensional attributes; balancing machines and systems, which dynamically measure and/or correct machine or component balance; biological microscopes, which typically are used to study organisms and their vital processes; bore and ID gauges, which are designed for internal diameter dimensional measurement or assessment; boroscopes, which are inspection tools with rigid or flexible optical tubes for interior inspection of holes, bores, cavities, and the like; calipers, which typically use a precise slide movement for inside, outside, depth or step measurements, some of which are used for comparing or transferring dimensions; CMM probes, which are transducers that convert physical measurements into electrical signals, using various measuring systems within the probe structure; color and appearance instruments, which, for example, typically are used to measure the properties of paints and coatings including color, gloss, haze and transparency; color sensors, which register items by contrast, true color, or translucent index, and are based on one of the color models, most commonly the RGB model (red, green, blue); coordinate measuring machines, which are mechanical systems designed to move a measuring probe to determine the coordinates of points on a work piece surface; depth gauges, which are used to measure of the depth of holes, cavities or other component features; digital/video microscopes, which use digital technology to display the magnified image; digital readouts, which are specialized displays for position and dimension readings from inspection gauges and linear scales, or rotary encoders on machine tools; dimensional gauges and instruments, which provide quantitative measurements of a product's or component's dimensional and form attributes such as wall thickness, depth, height, length, I.D., O.D., taper or bore; dimensional and profile scanners, which gather two-dimensional or three-dimensional information about an object and are available in a wide variety of configurations and technologies; electron microscopes, which use a focused beam of electrons instead of light to “image” the specimen and gain information as to its structure and composition; fiberscopes, which are inspection tools with flexible optical tubes for interior inspection of holes, bores, and cavities; fixed gauges, which are designed to access a specific attribute based on comparative gauging, and include angle gauges, ball gauges, center gauges, drill size gauges, feeler gauges, fillet gauges, gear tooth gauges, gauge or shim stock, pipe gauges, radius gauges, screw or thread pitch gauges, taper gauges, tube gauges, u.s. standard gauges (sheet/plate), weld gauges and wire gauges; specialty/form gauges, which are used to inspect parameters such as roundness, angularity, squareness, straightness, flatness, runout, taper and concentricity; gauge blocks, which are manufactured to precise gaugemaker tolerance grades for calibrating, checking, and setting fixed and comparative gauges; height gauges, which are used for measuring the height of components or product features; indicators and comparators, which measure where the linear movement of a precision spindle or probe is amplified; inspection and gauging accessories, such as layout and marking tolls, including hand tools, supplies and accessories for dimensional measurement, marking, layout or other machine shop applications such as scribes, transfer punches, dividers, and layout fluid; interferometers, which are used to measure distance in terms of wavelength and to determine wavelengths of particular light sources; laser micrometers, which measure extremely small distances using laser technology; scatterometers, which measure features by the scattering pattern, wavelength, or incident angle of light diffracted; levels, which are mechanical or electronic tools that measure the inclination of a surface relative to the earth's surface; machine alignment equipment, which is used to align rotating or moving parts and machine components; magnifiers, which are inspection instruments that are used to magnify a product or part detail via a lens system; master and setting gauges, which provide dimensional standards for calibrating other gauges; measuring microscopes, which are used by toolmakers for measuring the properties of tools, and often are used for dimensional measurement with lower magnifying powers to allow for brighter, sharper images combined with a wide field of view; metallurgical microscopes, which are used for metallurgical inspection; micrometers, which are instruments for precision dimensional gauging including a ground spindle and anvil mounted in a C-shaped steel frame.

Examples of further characterization techniques include, but are not limited to Noncontact laser micrometers are also available; microscopes (all types), which are instruments that are capable of producing a magnified image of a small object; optical/light microscopes, which use the visible or near-visible portion of the electromagnetic spectrum; optical comparators, which are instruments that project a magnified image or profile of a part onto a screen for comparison to a standard overlay profile or scale; plug/pin gauges, which are used for a “go/no-go” assessment of hole and slot dimensions or locations compared to specified tolerances; protractors and angle gauges, which measure the angle between two surfaces of a part or assembly; ring gauges, which are used for “go/no-go” assessment compared to the specified dimensional tolerances or attributes of pins, shafts, or threaded studs; rules and scales, which are flat, graduated scales used for length measurement, and which for OEM applications, digital or electronic linear scales are often used; snap gauges, which are used in production settings where specific diametrical or thickness measurements must be repeated frequently with precision and accuracy; specialty microscopes, which are used for specialized applications including metallurgy, gemology, or use specialized techniques like acoustics, vibration, or microwaves to perform their function; squares, which are used to indicate if two surfaces of a part or assembly are perpendicular; styli, probes, and cantilevers, which are slender rod-shaped stems and contact tips or points used to probe surfaces in conjunction with profilometers, SPMs, CMMs, gauges and dimensional scanners; surface profilometers, which measure surface profiles, roughness, waviness and other finish parameters by scanning a mechanical stylus across the sample or through noncontact methods; thread gauges, which are dimensional instruments for measuring thread size, pitch or other parameters; videoscopes, which are inspection tools that capture images from inside holes, bores or cavities; optical tools that use IR, UV, x-ray, and visible light to inspect surfaces, and the like.

### EXAMPLES

### Example

According to some embodiments, the materials and methods used in demonstrating the present invention are disclosed below. Perfluoropolyether dimethacrylate (perfluoropolyether DMA) was fabricated as described in Rolland, J. P., et al., J. Am. Chem. Soc., 2004. 126: p. 2322-2323, which is incorporated herein by reference in its entirety including all references cited therein. AFM micrographs were recorded in tapping mode on a Digital Instruments D3100 atomic force microscope. SEM images were performed on a JEM 6300 scanning electron microscope made by JEOL, Inc. Optical microscopy images were recorded on a Zeiss Axioskop 2 MAT Incident Light Microscope. X-ray photoelectron spectroscopy (XPS) spectra were captured with a Kratos Analytical Axis Ultra with a monochromatic Al source. The dual damascene master was acquired from International Sematech.

### Example 1

The fluoroelastomer-based molds were made by pouring an approximately 1 mm thick liquid film of perfluoropolyether-DMA, containing photoinitiator, onto the clean, patterned master. The material was then subjected to 365 nm UV light for 5-10 minutes under a nitrogen purge. After curing, the approximately 1 mm thick mold was carefully peeled from the master without employing a surface fluorination step. The perfluoropolyether-based molds were analyzed, via optical and atomic force microscopy, and then used to micromold an organic photopolymer resin, trimethylopropane triacrylate (TMPTA) formulated with a photoinitiator.

### Example 2

### Nanometer-Scale Imprint Lithography

We have proven the ability to generate high-fidelity replica perfluoropolyether molds of nanometer-sized features using a master template with 70 nm wide lines separated by 140 nm spaces. To test the limitations of the photocurable perfluoropolyether-based liquids in imprint lithography, we attempted to fabricate molds from single-walled carbon nanotubes grown on a silicon surface having diameters of 1-2 nm. AFM images of the surface-grown nanotubes were taken, along with perfluoropolyether replicates made from polymer precursor materials having molecular weights of 1000 and 4000 Da. Successful replication occurred in both cases; however, the 1000 MW perfluoropolyether produced a mold with higher resolution. This is presumably due to some slight relaxation of the 4000 MW polymeric material upon release of its confinement from the nanotube master, as the radius of gyration is greater, and thus the modulus is lower than that of the lower MW perfluoropolyether. The molds were used in turn to nanoimprint TMPTA resin using 50 to 150 N of force on the perfluoropolyether stamp. The perfluoropolyether stamp peeled off the carbon nanotubes easily, due to the low surface energy of the material and its oleophobic nature. The height and widths of the imprinted TMPTA nanotubes appear to be comparable to the original carbon master; quantitative measurements are limited by the resolution of the AFM tip.

### Example 3

### Imprint Lithography of Dual Damascene Features

The development of dual damascene technology has been a key aspect of integrated circuit (IC) feature minimization, as it lowers the number of processing steps, eliminates metal etch, reduces production cost, minimizes problems with lithographic overlap tolerance, and the like. Even though this technology reduces the number of overall processing steps, there are still about 20 steps associated with each wiring layer. Imprint lithography provides a straightforward method to reduce these steps; when the imprinted material is a functional dielectric, the number of steps can be reduced by a third.

To demonstrate patterning of dual damascene structures, we have fabricated perfluoropolyether based molds and created TMPTA replicates of complex, 3D structures, building a platform for more functional imprinting of dielectric materials. FIG. 2 shows molding and replication of a trench and via dual damascene structure. These particular dual damascene structures are larger (e.g., 100's of nanometers) to simplify initial process development and eventual electrical testing. The perfluoropolyether based fluoroelastomer materials generated excellent, high fidelity replica molds of the nanoscale features on the patterned silicon wafer master. The trenches of the perfluoropolyether based replica mold had an average height of 580 nm which was in excellent agreement with the measured 581 nm height of the features in the silicon master, see FIG. 4. The mold and master measurements differed with respect to trench width, most likely due to relaxation of the 4000 MW perfluoropolyether material, and via width and height. However, these aberrations are not translated into the TMPTA replicate, see FIG. 3c, which has corresponding measurements to the dual damascene master within measurement error. This suggests that the mold relaxation seen in the AFM is corrected when pressure is applied to create the replicate; the relaxation can also be improved by using a lower MW perfluoropolyether precursor.

The aberrations in height and width of the vias, shown in FIGS. 3 and 4, resulted from the limitation of AFM for imaging dual damascene structures. In fact, there is no current metrology method that can image these types of complex structures to specifications without cleaving the wafer. We demonstrate the use of perfluoropolyether molds as metrology tools for the non-destructive inspection of complex, high-aspect ratio features. A perfluoropolyether liquid precursor is poured on the desired film and cured in tens of seconds with UV light. When released from the wafer, the cured film possesses an exact negative replica of the original pattern. A variety of metrology and inspection methods can then be performed on the patterned, transparent film including microscopy, as the “holes” translate into “posts” which are simpler to image, and through-film optics which eliminates the challenges that scatterometry and ellipsometry method face with complex and multiple-material structures. Furthermore, the method is shown to be completely non-destructive to the original patterned wafer. Proof of the non-destructive nature of the method can be seen with reference to FIG. 5.

FIG. 5 shows XPS spectra of the wafer surface before (a) and after patterning (b), as well as patterning followed by a 5 second rinse with perfluorohexanes (c). In FIG. 5, XPS spectra data is shown of a dual damascene wafer before and after molding with perfluoropolyether materials: (i) shows survey spectra of the dual damascene master prior to molding (a); following molding with 4000 MW perfluoropolyether precursors (b); and after molding with 4000 MW perfluoropolyether precursors and a brief perfluorohexane wash (c); (ii) shows a higher resolution of the samples given in (i). Accordingly, FIG. 5 shows that the chemical composition of the surface has not changed. Looking more closely at the F 1s spectra, see FIG. 5ii, we show that the fluorine content at the surface has not changed; therefore the fluorinated polymer does not cause additional fluorine contamination.

### Example 4

### Patterned Structures Molded

FIG. 6 depicts some types of structures we have used for preliminary metrology testing. PFPE-DMA was dropcast over a 6 inch dual damascene test wafer. The wafer was placed in a sealed UV oven and purged with nitrogen for 10 minutes. The wafer was then exposed to 365 nm UV light for 5 minutes. The cured mold was slowly peeled from the wafer using tweezers and analyzed with microscopy.

Although the foregoing description is directed to the preferred embodiments of the invention, it is noted that other variations and modifications in the details, materials, steps and arrangement of parts, which have been herein described and illustrated in order to explain the nature of the preferred embodiment of the invention, will be apparent to those skilled in the art, and may be made without departing from the spirit or scope of the invention.

1. A method for performing metrology, comprising:
depositing a substance into communication with a component to be characterized, wherein the substance includes a low surface-energy curable polymer;
curing the substance such that a mold of the component is formed;
removing the cured substance mold from the component; and
inspecting the mold of the component to characterize the component.

2. The method of claim 1, wherein the component is substantially free from any residual substance following removing the cured substance from the component.

3. The method of claim 1, wherein the component comprises a silicon wafer.

4. The method of claim 1, wherein a volume of the substance before the curing is substantially equivalent to a volume of the cured substance after the curing.

5. The method of claim 1, wherein the substance substantially does not absorb hydrocarbon solvents.

6. The method of claim 1, wherein the substance does not swell more than about 10 percent by weight in the presence of a hydrocarbon solvent.

7. The method of claim 1, wherein the surface energy is less than about 20 dynes/cm.

8. The method of claim 1, wherein the surface energy is less than about 15 dynes/cm.

9. The method of claim 1, wherein the surface energy is less than about 12 dynes/cm.

10. The method of claim 1, wherein the cured substance is substantially non wettable.

11. The method of claim 1, wherein the cured substance has a wetting angle of less than about 90 degrees.

12. The method of claim 1, wherein the substance includes a fluoropolymer.

13. The method of claim 12, wherein the fluoropolymer includes perfluoropolyether.

14. The method of claim 13, wherein the perfluoropolyether includes a molecular weight of between about 500 and about 5000.

15. The method of claim 13, wherein the perfluoropolyether material comprises a backbone structure, wherein the backbone structure is selected from the group consisting of: 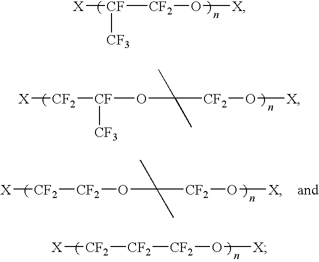
and wherein:
X is present or absent, and when present includes an endcapping group, and n is any positive integer.

16. The method of claim 15, wherein the endcapping group includes a polymerizable group.

17. The method of claim 16, wherein the polymerizable group includes an acrylate, a methacrylate, an epoxy, a styrenic group, or combinations thereof.

18. The method of claim 1, wherein the substance includes a siloxane.

19. The method of claim 18, wherein the siloxane includes poly(dimethyl siloxane).

20. The method of claim 1, wherein the curable polymer includes a fluoropolymer having a thermal-curable functional group.

21. The method of claim 1, wherein the curable polymer includes a fluoropolymer having a photocurable functional group.

22. The method of claim 21, wherein the photocurable functional group includes a photocurable diurethane methacrylate.

23. The method of claim 21, wherein the photocurable functional group includes a photocurable diepoxy.

24. The method of claim 21, wherein the photocurable functional group comprises a photocurable diurethane methacrylate functionalized perfluoropolyether having a structure of:

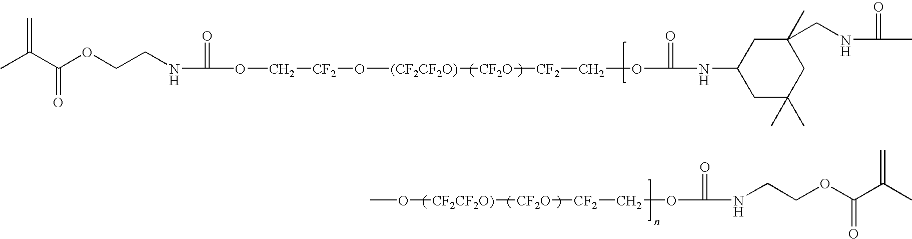

25. The method of claim 21, wherein the photocurable functional group comprises a photocurable diurethane methacrylate functionalized perfluoropolyether having a structure of:

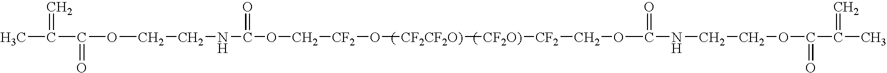

26. The method of claim 21, wherein the photocurable functional group comprises a photocurable diurethane methacrylate functionalized perfluoropolyether having a structure of:

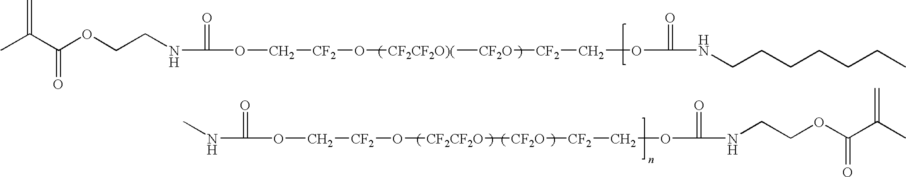

27. The method of claim 21, wherein the photocurable functional group comprises a photocurable diepoxy functionalized perfluoropolyether having a structure of:

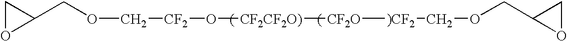

28. The method of claim 1, wherein the curable polymer includes a fluoropolymer having more than one of the following: a photocurable functional group, a thermal-curable functional group.

29. The method of claim 1, wherein characterizing is selected from the group consisting of measuring, scanning, inspecting, graphically representing, reading, computer generated graphic representation, microscopy, electron microscopy, and atomic force microscopy.

30. A silicon wafer metrology method, comprising:
depositing a substance into communication with a patterned surface of a silicon wafer to be characterized, wherein the substance includes a low surface-energy curable polymer;
curing the substance such that a mold of the patterned surface is formed;
removing the cured substance mold from the patterned surface; and
characterizing the mold of the patterned surface.

31. The method of claim 30, wherein the silicon wafer is returned to processing following removing the cured substance mold from the patterned surface of the silicon wafer.

32.-44. (canceled)

45. A metrology device, comprising:
a cured fluoropolymer replica of a device configured and dimensioned from a liquid fluoropolymer deposited on the patterned silicon wafer and cured thereupon.

46. (canceled)

47. (canceled)

48. The device of 45, wherein the device comprises a silicon wafer.

49. The device of claim 45, wherein the fluoropolymer includes a perfluoropolyether.

50.-69. (canceled)
